(19) United States
(12) Patent Application Publication
(10) Pub. No.: US 2020/0274053 A1
(43) Pub. Date: Aug. 27, 2020

(54) ELASTOMERIC PIEZOELECTRIC ELEMENT AND ELASTOMERIC PIEZOELECTRIC ELEMENT PRODUCTION METHOD

(71) Applicant: TOYODA GOSEI CO., LTD., Kiyosu-shi, Aichi-ken (JP)

(72) Inventors: Nozomu UESUGI, Kiyosu-shi, Aichi-ken (JP); Genki SAGO, Kiyosu-shi, Aichi-ken (JP); Yasuyuki NAKAMURA, Kiyosu-shi, Aichi-ken (JP); Kazumasa BABA, Kiyosu-shi, Aichi-ken (JP); Takashi HATANO, Kiyosu-shi, Aichi-ken (JP); Ryo IMAI, Kiyosu-shi, Aichi-ken (JP); Yuta MORIMURA, Kiyosu-shi, Aichi-ken (JP)

(21) Appl. No.: 16/647,195

(22) PCT Filed: Sep. 19, 2018
(86) PCT No.: PCT/JP2018/034660

§ 371 Date: Mar. 13, 2020

(30) Foreign Application Priority Data
Sep. 28, 2017 (JP) 2017-188514
Mar. 26, 2018 (JP) 2018-058648

(51) Int. Cl. H01L 41/083; H01L 41/047; H01L 41/18; H01L 41/277; H01L 41/37

(52) U.S. Cl. CPC H01L 41/083; H01L 41/0471; H01L 41/37; H01L 41/183; H01L 41/277; H01L 41/0478

(57) ABSTRACT

An elastomer piezoelectric element includes a plurality of unit layers disposed along a thickness direction of the elastomer piezoelectric element. Each of the unit layers includes a sheet-shaped dielectric elastomer dielectric portion, a conductive elastomer electrode partially disposed on a first surface of the dielectric portion, and an insulating elastomer insulated portion that is provided in at least a portion of an area surrounding the electrode and brings a thickness of the unit layer in a portion in which the electrode is not disposed close to a thickness of the unit layer in a portion in which the electrode is disposed.

### CROSS REFERENCE TO RELATED APPLICATIONS

This application is a U.S. national stage application of International Patent Application No. PCT/JP2018/034660 filed on Sep. 19, 2018, which claims priority to Japanese Patent Application No. 2017-188514 filed on Sep. 28, 2017 and Japanese Patent Application No. 2018-058648 filed on Mar. 26, 2018, the contents of which are incorporated herein by reference.

### BACKGROUND

The present invention relates to an elastomer piezoelectric element and a method for producing an elastomer piezoelectric element.

As disclosed in Patent Document 1 and Patent Document 2, an elastomer piezoelectric element constituted by a plurality of unit layers has been known. The unit layers are disposed along the thickness direction of the elastomer piezoelectric element. Each of the unit layers includes an elastomer dielectric portion and an electrode provided on the dielectric portion.

### PRIOR ART DOCUMENTS

### Patent Documents

Patent Document 1: Japanese Laid-Open Patent Publication No. 2012-125140
Patent Document 2: Japanese National Phase Laid-Open Patent Publication No. 2016-509826

As electrodes of the elastomer piezoelectric element, vapor deposited metal electrodes formed by metal vapor deposition, or conductive elastomer electrodes are used, for example. The conductive elastomer electrode has better follow-up ability to follow the displacement of the dielectric portion than a vapor deposited metal electrode. Therefore, when the conductive elastomer electrode is used, it is possible to improve the durability of the elastomer piezoelectric element against repeating of displacement of the dielectric portion.

However, the conductive elastomer electrode is formed to be thicker than the vapor deposited metal electrode. Therefore, as shown in FIG. 7A, an air layer 23 tends to be formed in an area surrounding an electrode 22 between dielectric portions 21 adjacent to each other in the thickness direction (the stacking direction). Such an air layer 23 is responsible for dielectric breakdown because of creeping discharge. In addition, as a method for eliminating the air layers 23, in the production of an elastomer piezoelectric element, the adjacent dielectric portions 21 may be pressed in the stacking direction in such a way that the adjacent dielectric portions 21 are contacted with each other. However, in this case, as shown in FIG. 7B, a portion of the dielectric portion 21 is deformed to fill the air layer in the area surrounding of the electrode 22, and this results in a portion 21a in which the dielectric portion 21 is a partially thin. As a result, dielectric breakdown tends to occur in the portion 21a.

It is an objective of the present invention to improve the durability of an elastomer piezoelectric element against dielectric breakdown.

To achieve the foregoing objective, an elastomer piezoelectric element is provided that includes a plurality of unit layers disposed along a thickness direction of the elastomer piezoelectric element. Each of the unit layers includes a sheet-shaped dielectric elastomer dielectric portion, a conductive elastomer electrode partially disposed on a first surface of the dielectric portion, and an insulating elastomer insulated portion that is provided in at least a portion of an area surrounding the electrode and brings a thickness of the unit layer in a portion in which the electrode is not disposed close to a thickness of the unit layer in a portion in which the electrode is disposed.

With the above-described configuration, the insulating elastomer insulated portion is disposed in the area surrounding the electrode in the unit layer. Therefore, a large air layer is unlikely to be formed in the area surrounding the electrode. In addition, even when an air layer is formed in the area surrounding the electrode, creeping discharge is unlikely to occur because the insulated portion acts as a barrier.

In addition, since the insulated portion is provided, the difference between the thickness of the unit layer in the portion in which the electrode is disposed and the thickness of the unit layer in the portion in which the electrode is not disposed is small. In other words, the surface on the side on which the electrode in the unit layer is disposed is flattened. Therefore, when external force such as that in pressing is exerted, the shape of the dielectric portion tends to be maintained, and a portion in which the dielectric portion is partially thin is unlikely to occur between the adjacent electrodes.

In the above-described elastomer piezoelectric element, the insulated portion is preferably constituted by a same material as a material of the dielectric portion.

The above-described configuration reduces the number of types of materials constituting the elastomer piezoelectric element.

In the above-described elastomer piezoelectric element, the insulated portion is preferably constituted by a protruding portion obtained by protruding a portion of the dielectric portion from a side corresponding to the first surface.

In the above-described configuration, an interface (joint surface) is not present between the dielectric portion and the insulated portion. Therefore, the inhibition of the displacement of the dielectric portion by the above-described interface is suppressed.

In the above-described elastomer piezoelectric element, the electrode preferably contains an insulating polymer and a conductive filler, and the insulated portion preferably contains a same insulating polymer as the insulating polymer contained in the electrode.

The above-described configuration reduces the number of types of materials constituting the elastomer piezoelectric element.

To achieve the foregoing objective, a method for producing an elastomer piezoelectric element includes: a unit layer forming step of forming a unit layer, the unit layer including a sheet-shaped dielectric elastomer dielectric portion, a conductive elastomer electrode partially disposed on a first surface of the dielectric portion, and an insulating elastomer insulated portion that is provided in at least a portion of an area surrounding the electrode and brings a thickness of the unit layer in a portion in which the electrode is not disposed close to a thickness of the unit layer in a portion in which the electrode is disposed; and a stacking step of stacking and joining a plurality of the unit layers each formed by the unit layer forming step together.

After forming the dielectric portion, it is preferably to form the electrode and the insulated portion on the first surface of the dielectric portion in the unit layer forming step.

In the unit layer forming step, it is preferable to form the dielectric portion in such a way that the dielectric portion has a protruding portion that protrudes from a side corresponding to the first surface and constitutes the insulated portion.

According to the above-described method for producing the elastomer piezoelectric element, with regard to each of the unit layers used in the stacking step, the difference between the thickness of the portion of the unit layer in which the electrode is disposed and the thickness of the portion of the unit layer in which the electrode is not disposed is small. In other words, the surface on the side on which the electrode in the unit layer is disposed is flattened.

In the stacking step, the flattened unit layers are stacked. As a result, a large air layer is not formed in the area surrounding the electrode. In addition, even when the stacked unit layers are pressed in the stacking direction, the deformation of the dielectric portion toward the electrode is suppressed because of the presence of the insulated portion, and a portion in which the dielectric portion is partially thin is unlikely to occur between the adjacent electrodes.

To achieve the foregoing objective, a method for producing the elastomer piezoelectric element includes: a first step of forming the electrode on a portion of a top surface of the dielectric portion formed in advance; and a second step of forming the dielectric portion and the insulated portion by applying a source material composition of a dielectric elastomer onto at least a portion of an area surrounding the electrode on the top surface of the dielectric portion formed in advance and onto a top surface of the electrode, and curing the applied source material composition.

With the above-described configuration, in the second step, when the source material composition of the dielectric elastomer is applied, the top surface of the applied source material composition is subjected to leveling to be nearly level. Therefore, the difference in height between the top surface of a portion of the applied source material composition, which has been applied to the electrode, and the top surface of a portion of the applied source material composition, which has been applied to the dielectric portion, is small. As a result, it is possible to form a unit layer in which the difference between the thickness of the portion in which the electrode is disposed and the thickness of the portion in which the electrode is not disposed is small.

In the above-described method for producing the elastomer piezoelectric element, it is preferable to repeatedly perform the first step and the second step. In this case, it is possible to perform continuous formation of multiple unit layers that constitute the elastomer piezoelectric element and are disposed along the thickness direction of the elastomer piezoelectric element.

According to the present invention, it is possible to improve the durability of the elastomer piezoelectric element against dielectric breakdown.

### BRIEF DESCRIPTION OF THE DRAWINGS

FIG. 1 is a cross-sectional view showing the schematic configuration of an elastomer piezoelectric element.

FIGS. 2A and 2B are partial cross-sectional views showing the relationship of the dielectric portion, an electrode, and an insulated portion.

FIG. 3 is an illustrative diagram showing a first method for producing an elastomer piezoelectric element.

FIG. 4 is an illustrative diagram showing a second method for producing an elastomer piezoelectric element.

FIG. 5 is a cross-sectional view showing a modification of the schematic configuration of an elastomer piezoelectric element.

FIG. 6 is an illustrative diagram showing a modification of the stacking step.

FIGS. 7A and 7B are cross-sectional views of a conventional elastomer piezoelectric element.

FIG. 8 is an illustrative diagram showing a third method for producing the elastomer piezoelectric element.

FIGS. 9A and 9B are cross-sectional views showing modifications of the schematic configuration of the elastomer piezoelectric element.

### DETAILED DESCRIPTION OF THE PREFERRED EMBODIMENTS

An elastomer piezoelectric element according to an embodiment will be described below.

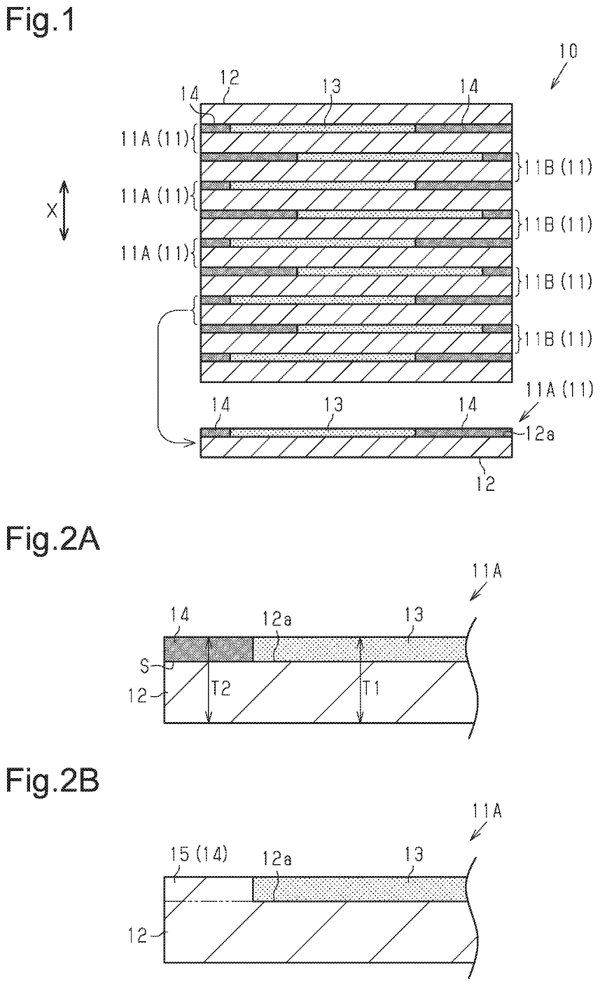

As shown in FIG. 1, an elastomer piezoelectric element 10 is a multi-layered structure including a plurality of unit layers 11 disposed along a thickness direction X of the elastomer piezoelectric element 10. In particular, a plurality of unit layers 11 is constituted by a plurality of first unit layers 11A and a plurality of second unit layers 11B. As shown in FIG. 1, in the elastomer piezoelectric element 10, the first unit layers 11A and the second unit layers 11B are alternately disposed in the thickness direction X.

As shown in FIGS. 1 and 2A, the first unit layer 11A includes a dielectric elastomer dielectric portion 12 in the form of a sheet having a constant thickness. The dielectric portion 12 is formed into a thin film, and has a thickness of, for example, 20 to 200 μm.

The dielectric elastomer constituting the dielectric portion 12 (material of the dielectric portion 12) is not limited in particular, and a dielectric elastomer for use in a known elastomer piezoelectric element can be employed. Examples of the above-described dielectric elastomer include polyrotaxanes, silicone elastomers, acrylic elastomers, and urethane elastomers. One of these dielectric elastomers can be used alone, or two or more of these dielectric elastomers can be used in combination.

An elastomer conductive electrode 13 is disposed at the central portion of a first surface 12a of the dielectric portion 12. The electrode 13 is formed into a thin film, and has a thickness of, for example, 10 to 100 μm. The conductive elastomer constituting the electrode 13 (a material of the electrode 13) is not limited in particular, and a conductive elastomer for use in a known elastomer piezoelectric element can be employed. Examples of the above-described conductive elastomer include a conductive elastomer containing an insulating polymer and a conductive filler.

Examples of the above-described insulating polymers include polyrotaxanes, silicone elastomers, acrylic elastomers, and urethane elastomers. One of these insulating polymers can be used alone, or two or more of these insulating polymers can be used in combination. Examples of the above-described conductive filler include Ketjen black (R), carbon black, and particles of metal. Examples of particles of metal include copper and silver. One of these conductive fillers can be used alone, or two or more of these conductive fillers can be used in combination.

On the entire surface of a portion of the first surface 12a of the dielectric portion 12 in which the electrode 13 is not disposed, an insulating elastomer insulated portion 14 is provided. The thickness of the insulated portion 14 is identical to the thickness of the electrode 13. Therefore, as shown in FIG. 2A, the thickness T1 of the first unit layer 11A in a portion in which the electrode 13 is disposed and the thickness T2 of the first unit layer 11A in a portion in which the electrode 13 is not disposed are identical to each other. In particular, the above-described thickness T1 corresponds to the sum of the thickness of the dielectric portion 12 and the thickness of the electrode 13, and the above-described thickness T2 corresponds to the sum of the thickness of the dielectric portion 12 and the thickness of the insulated portion 14.

As the insulating elastomer constituting the insulated portion 14 (a material of the insulated portion 14), a known insulating elastomer for use in an insulated portion in a known elastomer piezoelectric element or the like can be employed. Examples of the above-described insulating elastomer include polyrotaxanes, silicone elastomers, acrylic elastomers, and urethane elastomers. One of these insulating elastomers can be used alone, or two or more of these insulating elastomers can be used in combination.

The insulating elastomer constituting the insulated portion 14 preferably includes an insulating polymer contained in the electrode 13. In addition, it is more preferable that the component of the largest amount in the insulating polymer contained in the electrode 13 be the same as the component of the largest amount in the insulating polymers contained in the insulated portion 14. For example, the insulated portion 14 is preferably constituted by a material having a composition obtained by eliminating the conductive filler from the conductive elastomer constituting the electrode 13. In addition, the insulating elastomer constituting the insulated portion 14 may be the same as or different from the dielectric elastomer constituting the dielectric portion 12.

An interface S (joint surface) may be present or does not need to be present between the dielectric portion 12 and the insulated portion 14 in the first unit layer 11A. For example, when the dielectric portion 12 and the insulated portion 14 are separately formed and subsequently joined to each other, an interface S is formed between the dielectric portion 12 and the insulated portion 14. Furthermore, in the case where the same dielectric elastomer as the dielectric elastomer constituting the dielectric portion 12 is used as the insulating elastomer constituting the insulated portion 14 and where an insulated portion 14 is provided as a portion of the dielectric portion 12, an interface S is not formed between the dielectric portion 12 and the insulated portion 14. In this case, specifically, a protruding portion 15 protruding from the side corresponding to the first surface 12a is provided at a portion of the first surface 12a of the dielectric portion 12 in which the electrode 13 is not disposed in such a way that the thickness of the dielectric portion 12 is increased. As a result, an insulated portion 14 is constituted by this protruding portion 15 as shown in FIG. 2B.

The configuration of the second unit layer 11B is the same as the configuration of the first unit layer 11A, except for the fact that the disposition of the electrode 13 and the disposition of the insulated portion 14 on the first surface 12a of the dielectric portion 12 are different from each other. In particular, as shown in FIG. 1, in the first unit layer 11A, the electrode 13 is disposed at a position that is located at the central portion of the first surface 12a of the dielectric portion 12 but is shifted toward one side in a specific direction. Furthermore, in the first unit layer 11A, the insulated portion 14 is disposed at the remaining portion of the first surface 12a of the dielectric portion 12 in which the electrode 13 is not disposed. In contrast, in the second unit layer 11B, the electrode 13 is disposed at a position that is located at the central portion of the first surface 12a of the dielectric portion 12 but is shifted toward the other side in the specific direction. Furthermore, in the second unit layer 11B, the insulated portion 14 is disposed at the remaining portion of the first surface 12a of the dielectric portion 12 in which the electrode 13 is not disposed.

The above-described first unit layer 11A and the second unit layer 11B are alternately disposed in the thickness direction X (the stacking direction). As a result, an elastomer piezoelectric element 10 in which the dielectric portion 12 is disposed between two electrodes 13 adjacent in the stacking direction is constituted. The number of the unit layers 11 is not limited in particular; however, by way of example, the total number of the first unit layers 11A and the second unit layers 11B is 5 to 1000. Furthermore, in the present embodiment, a dielectric portion 12 is provided on the first unit layer 11A disposed at the uppermost layer to cover the electrode 13 and the insulated portion 14.

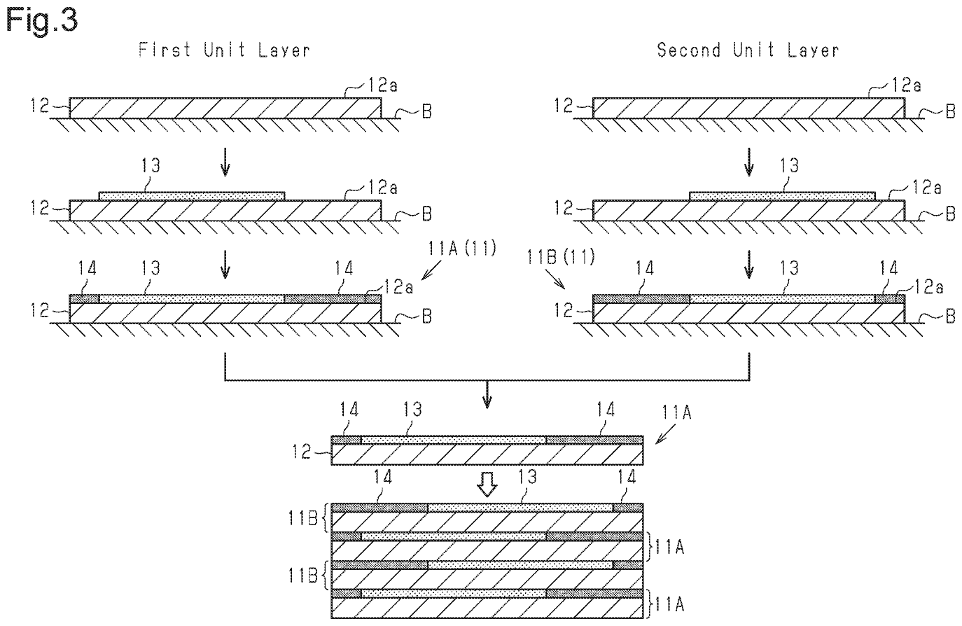

Next, a first method for producing an elastomer piezoelectric element 10 will be described with reference to FIG. 3. The elastomer piezoelectric element 10 is produced by performing a unit layer forming step and a stacking step described below in a sequential manner

Unit Layer Forming Step

The unit layer forming step is a step of forming a unit layer 11 including a dielectric portion 12, an electrode 13, and an insulated portion 14. In the unit layer forming step, a first unit layer 11A and a second unit layer 11B are formed, in which the first unit layer 11A and the second unit layer 11B are different in the disposition of the electrode 13 and the disposition of the insulated portion 14 in the first surface 12a of the dielectric portion 12.

First, an apparatus such as a slit die coater is used to apply a source material composition of a dielectric elastomer having a low viscosity onto the surface of an easily peelable substrate B such as a release sheet. Thereafter, a dielectric elastomer dielectric portion 12 having a constant thickness is formed by subjecting the source material composition of the applied dielectric elastomer to curing treatment such as heating or crosslinking.

Next, a source material composition of a conductive elastomer having a low viscosity is applied onto a specific portion of the first surface 12a of the dielectric portion 12. Then, an elastomer conductive electrode 13 is formed by subjecting the source material composition of the applied conductive elastomer to curing treatment. Thereafter, a source material composition of an insulating elastomer having a low viscosity is applied onto a portion of the first surface 12a of the dielectric portion 12 in which the electrode 13 is not formed in such a way that the thickness of the applied source material composition is identical to the thickness of the electrode 13. Then, the source material composition of the applied insulating elastomer is subjected to curing treatment to form an insulating elastomer insulated portion 14. Examples of the method for application of each of the source material compositions of the conductive elastomer and the insulating elastomer include a method for application by ink jet printing, and a method for application by spraying or the like using masks having patterns corresponding to an electrode 13 or an insulated portion 14.

Then, a film-shaped material including the dielectric portion 12, the electrode 13, and the insulated portion 14 is peeled away from the substrate B to obtain a unit layer 11 in which the thickness of a portion in which the electrode 13 is disposed and the thickness of a portion in which the electrode 13 is not disposed are identical to each other. If necessary, the resulting unit layer 11 is subjected to compression treatment such as isostatic pressing under vacuum.

Stacking Step

The stacking step is a step of stacking and joining a plurality of unit layers 11 together, in which each of the unit layers 11 has been formed by the unit layer forming step.

First, the surface on which the electrode 13 and the insulated portion 14 are located in the first unit layer 11A is placed to be opposed to the surface on which the dielectric portion 12 is located in the second unit layer 11B, and the first unit layer 11A and the second unit layer 11B are pressed against each other to join the first unit layer 11A and the second unit layer 11B.

In the same manner as described above, the above-described processes are repeatedly performed in such a way that the first unit layer 11A and the second unit layer 11B are alternately stacked. As a result, an elastomer piezoelectric element 10 is obtained, which is constituted by a plurality of unit layers 11 each including a dielectric portion 12, an electrode 13, and an insulated portion 14.

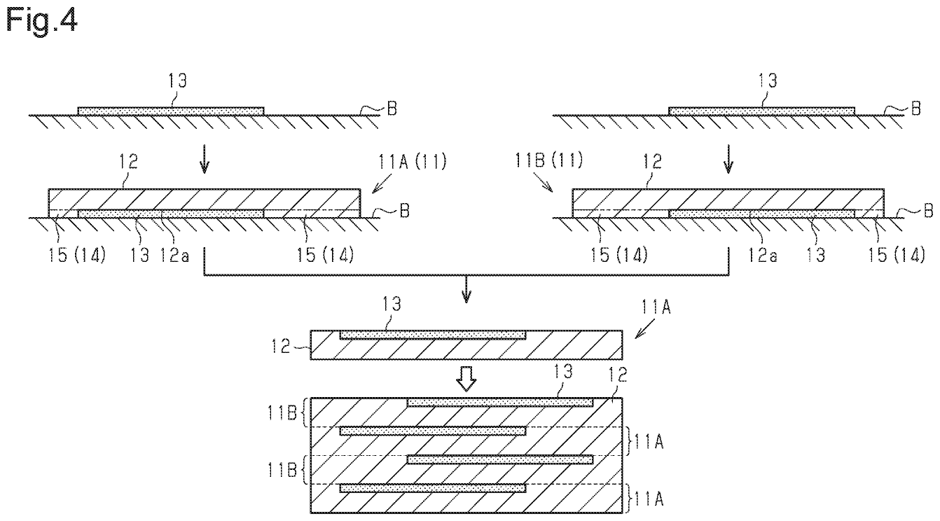

Next, a second method for producing an elastomer piezoelectric element 10 will be described with reference to FIG. 4. The second production method is different from the first production method in that the insulated portion 14 is formed as a portion of the dielectric portion 12 in the unit layer forming step.

Unit Layer Forming Step

First, a source material composition of a conductive elastomer having a low viscosity is applied onto the surface of the substrate B. Then, the source material composition of the applied conductive elastomer is subjected to curing treatment to form an elastomer conductive electrode 13. Next, a source material composition of a dielectric elastomer having a low viscosity is applied onto the surface of the substrate B in a range broader than the electrode 13 in such a way that the top of the electrode 13 and an area surrounding the electrode 13 are covered with the applied source material composition. Then, the source material composition of the applied dielectric elastomer is subjected to curing treatment. As a result, the electrode 13 is disposed on the first surface 12a, and in addition, a dielectric portion 12 having a protruding portion 15 protruding from the side corresponding to the first surface 12a is formed in an area surrounding the electrode 13. In this case, the protruding portion 15 of the dielectric portion 12 constitutes the insulated portion 14.

Then, a film-shaped material including the dielectric portion 12 and the electrode 13 is peeled away from the substrate B to obtain a unit layer 11 in which the thickness of a portion in which the electrode 13 is disposed and the thickness of a portion in which the electrode 13 is not disposed are identical to each other. If necessary, the resulting unit layer 11 is subjected to compression treatment.

The insulated portion 14 of the unit layer 11 obtained by the above-described step is a portion (protruding portion 15) of the dielectric portion 12 formed to be integrated into the dielectric portion 12. Therefore, an interface S (joint surface) is not present between the dielectric portion 12 and the insulated portion 14 in the unit layer 11 (see FIG. 2B).

Stacking Step

The stacking step in the second production method is the same as that of the first production method.

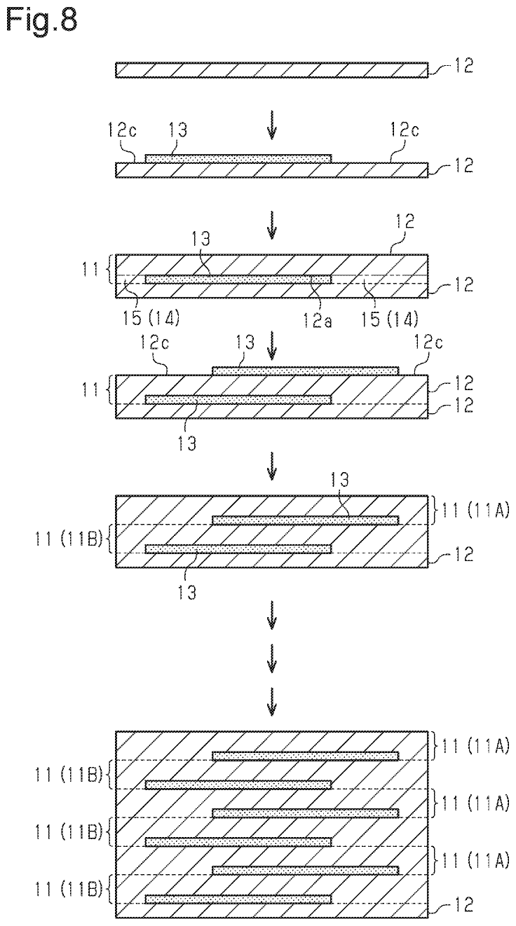

Next, a third method for producing an elastomer piezoelectric element 10 will be described with reference to FIG. 8. As described below, the first step of forming the electrode 13, and the second step of forming the dielectric portion 12 and the insulated portion 14 are repeatedly performed to form a new unit layer 11 directly on the unit layer 11 in a continuous manner. As a result, the elastomer piezoelectric element 10 is produced.

First, a source material composition of a dielectric elastomer having a low viscosity is applied onto the surface of the substrate. Then, the source material composition of the applied dielectric elastomer is subjected to curing treatment to form a dielectric portion 12 located at the outermost layer. In FIG. 8, the illustration of the substrate is omitted.

First Step

Onto a portion of the top surface of the dielectric portion 12 formed in advance, a source material composition of a conductive elastomer having a low viscosity is partially applied. Then, the source material composition of the applied conductive elastomer is subjected to curing treatment to form an elastomer conductive electrode 13. At this time, the top surface of the dielectric portion 12 is provided with an exposed portion 12c, which is located in an area surrounding the electrode 13, and in which the dielectric portion 12 is exposed.

Second Step

A source material composition of a dielectric elastomer having a low viscosity is applied to cover the top of the electrode 13 and the top of the exposed portion 12c of the dielectric portion 12. At this time, the applied source material composition is subjected to leveling in such a way that the top surface of the applied source material composition is nearly level based on the flowability of the applied source material composition itself. As a result, the difference in height between the top surface of the portion of the applied source material composition located on the electrode 13 and the top surface of the portion of the applied source material composition located on the exposed portion 12c is small.

Thereafter, the applied source material composition is subjected to curing treatment. As a result, the electrode 13 is disposed on the first surface 12a, and in addition, a dielectric portion 12 having a protruding portion 15 protruding from the side corresponding to the first surface 12a is formed in an area surrounding the electrode 13. In this case, the protruding portion 15 of the dielectric portion 12 constitutes the insulated portion 14.

As a result of performing the first step and the second step, a unit layer 11 including a dielectric portion 12, an electrode 13, and an insulated portion 14 is formed. Next, the first step and the second step are performed in the same manner by using the dielectric portion 12 constituting the top surface of the formed unit layer 11 as the dielectric portion 12 formed in advance. As a result, a new unit layer 11 is formed to be joined to the unit layer 11 formed in advance.

At this time, when the unit layer 11 formed in advance is a first unit layer 11A, the formation position of the electrode 13 and the dielectric portion 12 (insulated portion 14) in the first step and the second step is adjusted in such a way that a second unit layer 11B is formed as a new unit layer 11. In addition, when the unit layer 11 formed in advance is the second unit layer 11B, the formation position of the electrode 13 and the dielectric portion 12 (insulated portion 14) in the first step and the second step is adjusted in such a way that a first unit layer 11A is formed as a new unit layer 11.

Then, the first step and the second step are repeatedly performed until the number of the unit layers 11 reaches a predetermined number. As a result, an elastomer piezoelectric element 10 is obtained, which is constituted by a plurality of unit layers 11 each including a dielectric portion 12, an electrode 13, and an insulated portion 14. If necessary, the resulting elastomer piezoelectric element 10 is subjected to compression treatment such as isostatic pressing under vacuum.

The curing treatment in the first step and the second step are not limited in particular, and can be appropriately selected according to the employed source material composition. Examples of the curing treatment include heating, drying, and treatment with the addition of a curing agent.

In addition, the curing treatment in the first step and the second step may be treatment for setting the entirety of the applied source material composition to be in the completely cured state, or may be treatment for setting the applied source material composition to be in the semi-cured state. In other words, the curing treatment may be any curing treatment as long as a source material composition is cured by the treatment enough not to be mixed with a source material composition to be applied on the cured source material composition. When the curing treatment for setting the source material composition to be in the semi-cured state is performed, a stack obtained by repeatedly performing the first step and the second step is subjected to curing treatment for completely curing the portion in the semi-cured state.

In the first step and the second step, each of the source material compositions can be applied by using an applicator such as, for example, a die coater device, a bar coater device, and a dispenser. When the curing treatment for setting the source material composition to be in the semi-cured state, a source material composition is preferably applied on the portion in the semi-cured state in such a way that the portion in the semi-cured state is not in contact with a nozzle of the applicator. In addition, when the curing treatment for setting the source material composition to be in the cured state, a method for application using a mask having a predetermined pattern can also be employed.

The operation and advantages of the present embodiment will now be described.
(1) The elastomer piezoelectric element 10 includes a plurality of unit layers 11 disposed along a thickness direction X of the elastomer piezoelectric element 10. Each of the unit layers 11 includes a dielectric portion 12, an electrode 13, and an insulated portion 14. The insulated portion 14 is constituted by an insulating elastomer, and in addition, disposed in an area surrounding the electrode 13. Therefore, a large air layer is unlikely to be formed in the area surrounding the electrode 13. In addition, even when an air layer is formed in the area surrounding the electrode 13, creeping discharge is unlikely to occur since the insulated portion 14 acts as a barrier.

In addition, since the insulated portion 14 is provided, the thickness T1 of the unit layer 11 in a portion in which the electrode 13 is disposed and the thickness T2 of the unit layer 11 in a portion in which the electrode 13 is not disposed are identical to each other. In other words, the surface on the side on which the electrode 13 in the unit layer 11 is disposed is flattened. Therefore, when external force such as in pressing is exerted, the shape of the dielectric portion 12 tends to be maintained, and a portion in which the dielectric portion 12 is partially thin is unlikely to occur between the adjacent electrodes 13.

Therefore, according to the elastomer piezoelectric element 10 of the present embodiment, the durability against dielectric breakdown caused by creeping discharge and the durability against dielectric breakdown caused by the occurrence of a partially thin portion in the dielectric portion 12 are improved.

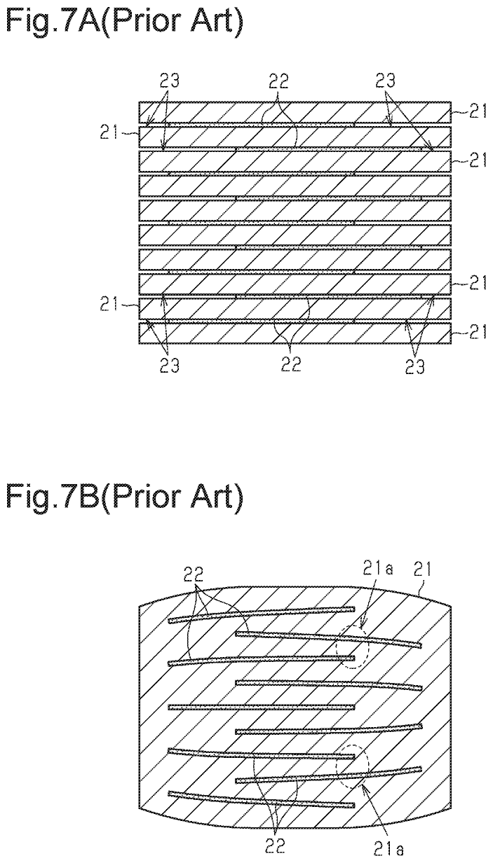

In addition, when a thin portion corresponding to a portion 21a in FIG. 7B is formed in the dielectric portion 12, the thickness of the dielectric portion 12 between the adjacent electrodes 13 is uneven. In this case, during activation, directions of displacement and directions of stress vectors in the respective portions vary from each other. As a result, the amount of displacement of the elastomer piezoelectric element 10 falls below the designed value.

In contrast, according to the elastomer piezoelectric element 10 of the present embodiment, the thickness of the dielectric portion 12 between the adjacent electrodes 13 is set to be even. Therefore, during activation, directions of displacement and directions of stress vectors are totally perpendicular to the activation surface. As a result, it is possible to ensure an amount of displacement approximate to a designed value.

(2) The insulated portion 14 is constituted by the same material as the material of the dielectric portion 12.

With the above-described configuration, it is possible to reduce the number of types of materials constituting the elastomer piezoelectric element 10.

(3) The insulated portion 14 is constituted by a protruding portion 15 obtained by protruding a portion of the dielectric portion 12 from the side corresponding to the first surface 12a.

With the above-described configuration, the interface S (joint surface) is not present between the dielectric portion 12 and the insulated portion 14. Therefore, the inhibition of the displacement of the dielectric portion 12 by the interface S is suppressed.

(4) The electrode 13 contains an insulating polymer and a conductive filler, and the insulated portion 14 contains the same insulating polymer as the insulating polymer contained in the electrode 13.

With the above-described configuration, it is possible to reduce types of materials constituting the elastomer piezoelectric element 10. In addition, it is possible to reduce the difference of follow-up ability from the displacement of the dielectric portion 12 by bringing the elasticity of the elastomer conductive electrode 13 close to the elasticity of the insulating elastomer insulated portion 14.

(5) The method for producing the elastomer piezoelectric element 10 (the first production method and the second production method) includes a unit layer forming step of forming a unit layer 11; and a stacking step of stacking a plurality of unit layers 11 each formed by the unit layer forming step to be joined to each other. The unit layer 11 includes a sheet-shaped dielectric elastomer dielectric portion 12, an elastomer conductive electrode 13 partially disposed on a first surface 12a of the dielectric portion 12, and an insulating elastomer insulated portion 14 provided in an area surrounding the electrode 13.

With the above-described configuration, in each of the unit layers 11 used in the stacking step, the thickness of the unit layer 11 in a portion in which the electrode 13 is disposed and the thickness of the unit layer 11 in a portion in which the electrode 13 is not disposed are identical to each other. In other words, the surface on the side on which the electrode 13 in the unit layer 11 is disposed is flattened.

In the stacking step, since the flattened unit layers 11 are stacked, no large air layer is formed in an area surrounding the electrode 13. In addition, even when the stacked unit layers 11 are pressed in the stacking direction, the deformation of the dielectric portion 12 toward the electrode 13 is suppressed by the presence of the insulated portion 14. As a result, a portion in which the dielectric portion 12 is partially thin is unlikely to occur between the adjacent electrodes 13.

(6) The method for producing an elastomer piezoelectric element 10 (the third production method) includes a first step of forming an electrode 13 on a portion of the top surface of a dielectric portion 12 formed in advance; and a second step of forming a dielectric portion 12 and an insulated portion 14 by applying a source material composition of a dielectric elastomer onto at least a portion of an area surrounding the electrode 13 on the top surface of the dielectric portion 12 formed in advance, and the top surface of the electrode 13, and curing the applied source material composition.

With the above-described configuration, in the second step, when a source material composition of the dielectric elastomer is applied, the top surface of the applied source material composition is subjected to leveling to be nearly level. As a result, the difference in height between the top surface of the portion of the applied source material composition located on the electrode 13 and the top surface of the portion of the applied source material composition located on the exposed portion 12c is small. In short, a source material composition of a dielectric elastomer is applied in such a way that the top surface of the source material composition is parallel to the top surface of the dielectric portion 12 formed in advance. As a result, it is possible to form a unit layer 11 in which the difference between the thickness of a portion in which the electrode 13 is disposed and the thickness of a portion in which the electrode 13 is not disposed is small.

In addition, with the above-described configuration, a unit layer 11 is formed in such a way that the unit layer 11 is joined on the dielectric portion 12 formed in advance. Therefore, the dielectric portion 12 formed in advance needs not to be subjected to a stacking step of stacking the unit layers 11 to be joined to each other. Therefore, the production step can be simplified by omitting the stacking step.

Furthermore, with the above-described configuration, in the second step, the source material composition of the dielectric elastomer is applied on the top of the dielectric portion 12 formed in advance (the exposed portion 12c) and the top of the electrode 13. At this time, the source material composition gets entry into minute depressions and projections present on the top of the dielectric portion 12 and the top of the electrode 13. As a result, adhesiveness between a dielectric portion 12 formed by curing the source material composition, and the dielectric portion 12 formed in advance and the electrode 13 is improved.

(7) The first step and the second step are repeatedly performed.

With the above-described configuration, a new unit layer 11 is formed in such a way that the new unit layer 11 is joined onto the unit layer 11 formed in advance. Therefore, it is possible to form a plurality of unit layers 11 disposed along a thickness direction X of the elastomer piezoelectric element 10 in a continuous manner.

In addition, the unit layers 11 are joined to each other without exerting external force such as pressing of the unit layers 11 against each other using a press. Therefore, the occurrence of distortions in the electrode 13, and the dielectric portion 12 between the electrodes 13 by external force exerted in the joining process is suppressed. As a result, an elastomer piezoelectric element 10 in which, during activation, directions of displacement and directions of stress vectors are totally perpendicular to the activation surface tends to be obtained.

The above-described embodiment may be modified as follows.

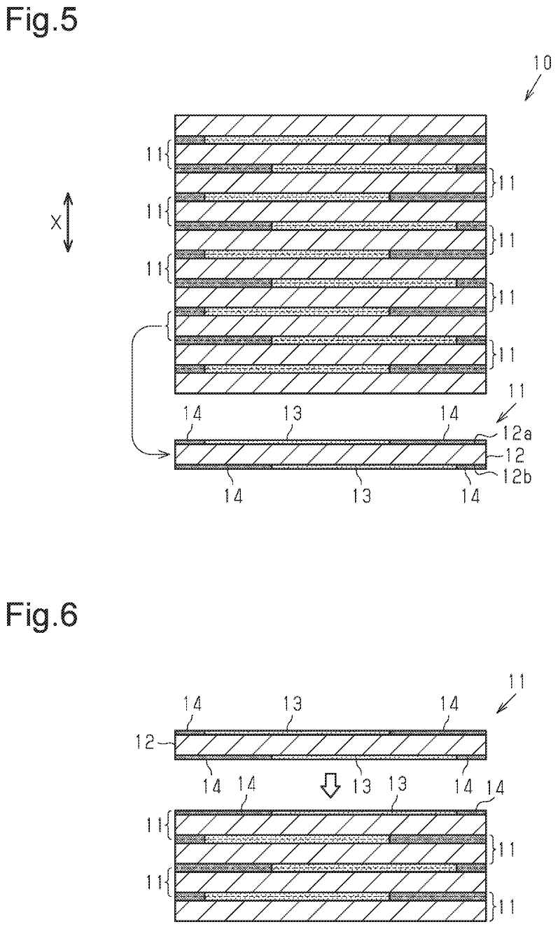

The configuration of the unit layer 11 is not limited to the configuration according to the above-described embodiment. For example, as shown in FIG. 5, the unit layer 11 may include a dielectric portion 12; an electrode 13 and an insulated portion 14 disposed on a first surface 12a of the dielectric portion 12; and an electrode 13 and an insulated portion 14 disposed on a second surface 12b of the dielectric portion 12. The above-described second surface 12b is the surface opposite to the first surface 12a in dielectric portion 12.

In this case, as shown in FIG. 6, in the stacking step, the unit layers 11 are stacked to be joined to each other in such a way that the electrodes 13 in the respective unit layers 11 lie over one another, and the insulated portions 14 in the respective unit layers 11 lie over one another. Furthermore, in this case, the joint surface between the adjacent unit layers 11 is not located in a dielectric portion 12, and it is therefore possible to employ a method by using an adhesive as the method for joining the unit layers 11 together.

The thickness of the insulated portion 14 may be smaller than the thickness of the electrode 13 constituting the same unit layer 11. In other words, the insulated portion 14 can have any configuration as long as the configuration results in the fact that, compared to the case where the insulated portion 14 is not provided, the thickness T2 of the unit layer 11 in a portion in which the electrode 13 is not disposed is close to the thickness T1 of the unit layer 11 in a portion in which the electrode 13 is disposed. As the thickness of the insulated portion 14 becomes closer to the thickness of the electrode 13, the degree of the effect of the above-described item (1) becomes larger.

In the first surface 12a of the dielectric portion 12, the range of the insulated portion 14 being provided is not limited to the entirety of a portion in which the electrode 13 is not disposed. In other words, the insulated portion 14 may be disposed in a portion in which the electrode 13 is not disposed in the first surface 12a of the dielectric portion 12.

With regard to the third production method, in the case of the above-described embodiment, the dielectric portion 12 and the insulated portion 14 are simultaneously formed by the second step; however, the dielectric portion 12 and the insulated portion 14 may be separately formed. For example, in the first step, a source material composition of a conductive elastomer having a low viscosity is partially applied onto a portion of the top surface of the dielectric portion 12 formed in advance. Then, the source material composition of the applied conductive elastomer is subjected to curing treatment, and in addition, a source material composition of an insulating elastomer having a low viscosity is partially applied onto a portion of the top surface of the dielectric portion 12 formed in advance. Then, the source material composition of the applied insulating elastomer is subjected to curing treatment to form an electrode 13 and an insulated portion 14. As a result, an insulated portion is disposed in at least a portion of an area surrounding the electrode 13. Then, in the second step, a dielectric portion 12 is formed by applying a source material composition of a dielectric elastomer onto the top surface of the electrode 13 and the top surface of the insulated portion 14, and curing the applied source material composition. Also, in this case, a new unit layer 11 can be formed directly on the unit layer 11 in a continuous manner.

The third production method may include a third step of stacking a plurality of stacks each formed by repeatedly performing the first step and the second step to be joined to each other.

The elastomer piezoelectric element 10 may include a common electrode connecting the electrodes 13 to be subjected to application of identical electric potentials with each other. In other words, the elastomer piezoelectric element 10 may include a first common electrode connecting the electrodes 13 constituting the first unit layers 11A with each other, and a second common electrode connecting the electrodes 13 constituting the second unit layers 11B with each other.

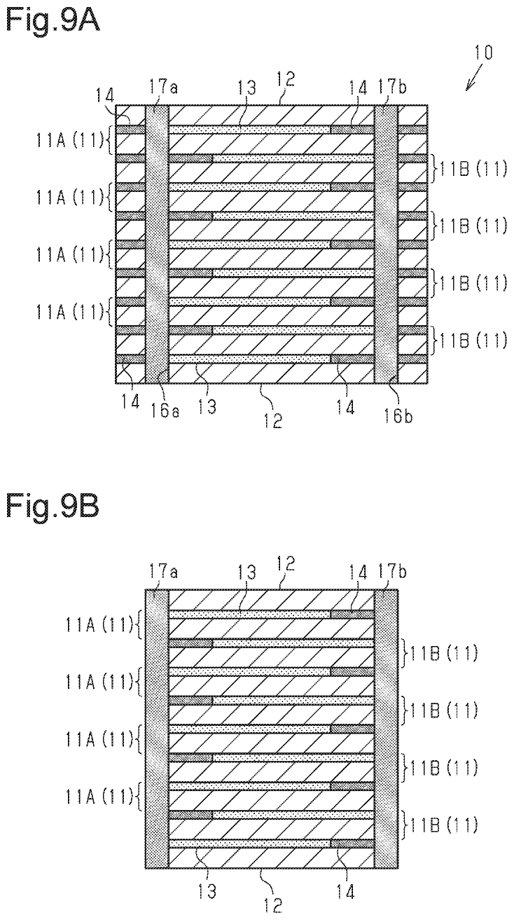

For example, as shown in FIG. 9A, a first hole 16a, which extends through the elastomer piezoelectric element 10 in the stacking direction, is provided by using a perforating punch or the like in such a way that the first hole 16a extends through each of the electrodes 13 that constitute the first unit layers 11A and are to be subjected to application of identical electric potentials. Furthermore, in the same manner as described above, a second hole 16b, which extends through the elastomer piezoelectric element 10 in the stacking direction, is provided in such a way that the second hole 16b extends through each of the electrodes 13 that constitute the second unit layers 11B and are to be subjected to application of identical electric potentials. Then, the interior of the first hole 16a is provided with a first common electrode 17a connected to each of the electrodes 13 that constitute the first unit layers 11A and are to be subjected to application of identical electric potentials. Furthermore, in the same manner as described above, the interior of the second hole 16b is provided with a second common electrode 17b connected to each of the electrodes 13 that constitute the second unit layers 11B and are to be subjected to application of identical electric potentials.

In addition, as shown in FIG. 9B, the electrodes 13 that constitute the first unit layers 11A and are to be subjected to application of identical electric potentials are exposed at a first edge of the elastomer piezoelectric element 10, such as by cutting off side portions of the elastomer piezoelectric element 10. Furthermore, in the same manner as described above, the electrodes 13 that constitute the second unit layers 11B and are to be subjected to application of identical electric potentials are exposed at a second edge of the elastomer piezoelectric element 10. Then, the first edge of the elastomer piezoelectric element 10 is provided with a first common electrode 17a connected to each of the electrodes 13 that constitute the first unit layers 11A and are to be subjected to application of identical electric potentials. Furthermore, in the same manner as described above, the second edge of the elastomer piezoelectric element 10 is provided with a second common electrode 17b connected to each of the electrodes 13 that constitute the second unit layer 11B and are to be subjected to application of identical electric potentials.

Technical concepts obtained from the above embodiment and the modified examples will now be described.

(A) The elastomer piezoelectric element, wherein the insulated portion is constituted by a material different from the dielectric portion.

(B) The elastomer piezoelectric element, wherein an interface is present between the dielectric portion and the insulated portion in the unit layer.

(C) The method for producing an elastomer piezoelectric element, comprising:
a first step of forming the electrode on a portion of a top surface of the dielectric portion formed in advance, and in addition, forming the insulated portion in at least a portion of an area surrounding the electrode on the top surface of the dielectric portion formed in advance; and a second step of forming the dielectric portion by applying a source material composition of a dielectric elastomer onto a top surface of the electrode and a top surface of the insulated portion, and curing the applied source material composition.

1. An elastomer piezoelectric element comprising a plurality of unit layers disposed along a thickness direction of the elastomer piezoelectric element, wherein each of the unit layers includes
a sheet-shaped dielectric elastomer dielectric portion,
a conductive elastomer electrode partially disposed on a first surface of the dielectric portion, and
an insulating elastomer insulated portion that is provided in at least a portion of an area surrounding the electrode and brings a thickness of the unit layer in a portion in which the electrode is not disposed close to a thickness of the unit layer in a portion in which the electrode is disposed.

2. The elastomer piezoelectric element according to claim 1, wherein the insulated portion is constituted by a same material as a material of the dielectric portion.

3. The elastomer piezoelectric element according to claim 2, wherein the insulated portion is constituted by a protruding portion obtained by protruding a portion of the dielectric portion from a side corresponding to the first surface.

4. The elastomer piezoelectric element according to claim 1, wherein
the electrode contains an insulating polymer and a conductive filler, and
the insulated portion contains a same insulating polymer as the insulating polymer contained in the electrode.

5. A method for producing an elastomer piezoelectric element, comprising:
a unit layer forming step of forming a unit layer, the unit layer including
a sheet-shaped dielectric elastomer dielectric portion,
a conductive elastomer electrode partially disposed on a first surface of the dielectric portion, and
an insulating elastomer insulated portion that is provided in at least a portion of an area surrounding the electrode and brings a thickness of the unit layer in a portion in which the electrode is not disposed close to a thickness of the unit layer in a portion in which the electrode is disposed; and
a stacking step of stacking and joining a plurality of the unit layers each formed by the unit layer forming step together.

6. The method for producing an elastomer piezoelectric element according to claim 5, comprising, after forming the dielectric portion, forming the electrode and the insulated portion on the first surface of the dielectric portion in the unit layer forming step.

7. The method for producing an elastomer piezoelectric element according to claim 5, comprising, in the unit layer forming step, forming the dielectric portion in such a way that the dielectric portion has a protruding portion that protrudes from a side corresponding to the first surface and constitutes the insulated portion.

8. The method for producing an elastomer piezoelectric element according to claim 7, comprising, after forming the electrode, forming the dielectric portion in such a way that the protruding portion is located in at least a portion of an area surrounding of the electrode in the unit layer forming step.

9. A method for producing the elastomer piezoelectric element according to claim 3, the method comprising:
a first step of forming the electrode on a portion of a top surface of the dielectric portion formed in advance; and
a second step of forming the dielectric portion and the insulated portion by
applying a source material composition of a dielectric elastomer onto at least a portion of an area surrounding the electrode on the top surface of the dielectric portion formed in advance and onto a top surface of the electrode, and
curing the applied source material composition.

10. The method for producing the elastomer piezoelectric element according to claim 9, comprising repeatedly performing the first step and the second step.
